(19) United States
(12) Patent Application Publication
(10) Pub. No.: US 2009/0001584 A1
(43) Pub. Date: Jan. 1, 2009

(54) SEMICONDUCTOR DEVICE AND METHOD FOR FABRICATING THE SAME

(76) Inventor: Sang-Chul Kim, Eumseong-gun (KR)

Correspondence Address: SHERR & VAUGHN, PLLC, 620 HERNDON PARKWAY, SUITE 200, HERNDON, VA, 20170, US

(21) Appl. No.: 12/142,923

(22) Filed: Jun. 20, 2008

(30) Foreign Application Priority Data
Jun. 26, 2007 (KR) 10-2007-0062804

(51) Int. Cl. H01L 21/768; H01L 23/532

(52) U.S. Cl. 257/751; 438/653; 257/E21.584; 257/E23.161

(57) ABSTRACT

A method of fabricating a semiconductor device that may include at least one of the following steps: Forming a lower metal wiring on and/or over a semiconductor substrate. Forming an interlayer insulating film having a damascene hole on and/or over the semiconductor substrate and the lower metal wiring. Forming an anti-diffusion film on and/or over the exposed lower metal wiring below the damascene hole and/or on side surfaces of the damascene hole. Selectively removing the anti-diffusion film formed on and/or over the exposed lower metal wiring at the bottom of the damascene hole using a plasma process that uses an inert gas.

This application claims priority under 35 U.S.C. 119 to Korean Patent Application No. P10-2007-0062804 (filed Jun. 26, 2007), which is hereby incorporated by reference in its entirety.

### BACKGROUND

Embodiments relates to a semiconductor device fabricated using a damascene process and/or a method of fabricating the same. Due to increasing complexity of integrated circuits, multilevel interconnecting processes may be desirable when fabricating semiconductor devices. To fulfill high integration-degree and/or high speed requirements of integrated circuits, a Copper (Cu) dual-damascene process may be used. A Cu dual-damascene process may be used to form interconnecting wirings in a metal-interlayer dielectric film having a relatively low dielectric constant k. Since copper has a relatively low resistance and relatively low electron transfer resistance, relatively low dielectric materials may be used to minimize negative RC delay effects of metal wiring connections. Using copper (Cu) wiring instead of aluminum (AL) wiring as a material choice may improve resistance characteristics. However, in addition to general material choices, it may be desirable to further maximize resistance characteristics in wiring as fabricated devices become smaller.

Often times, Cu dual-damascene processes have a drawback of having a relatively large contact resistance of vias that connect lower metal wiring (e.g. due to byproducts, such as polymers, etc. in the vias). In some circumstances, proper formation of the vias is impractical and/or very difficult, which may result in relatively low yield and/or relatively poor device reliability.

### SUMMARY

Embodiments relate to semiconductor devices and/or methods of fabricating semiconductor devices, which may have relatively low contact resistance in vias formed in a damascene process, may minimize byproducts present in vias, may improve gap-fill capabilities of upper metal wirings, and/or minimize defect rates.

Embodiments relate to a method of fabricating a semiconductor device that may include at least one of the following steps: Forming a lower metal wiring on and/or over a semiconductor substrate. Forming an interlayer insulating film having a damascene hole on and/or over the semiconductor substrate and the lower metal wiring. Forming an anti-diffusion film on and/or over the exposed lower metal wiring at the bottom of the damascene hole and/or on a side surface region of the damascene hole. Selectively removing the anti-diffusion film formed on and/or over the exposed lower metal wiring at the bottom of the damascene hole using a plasma process that uses an inert gas.

In embodiments, a semiconductor device may include at least one of: A lower metal wiring formed on and/or over a semiconductor substrate. An interlayer insulating film formed on and/or over the semiconductor substrate and the lower metal wiring; the interlayer insulating film may have a damascene hole formed to correspond to the lower metal wiring. An anti-diffusion film formed on and/or over side surfaces of the damascene hole. An upper metal wiring formed on and/or over the lower metal wiring at the bottom of the damascene hole and on the anti-diffusion film.

### DRAWINGS

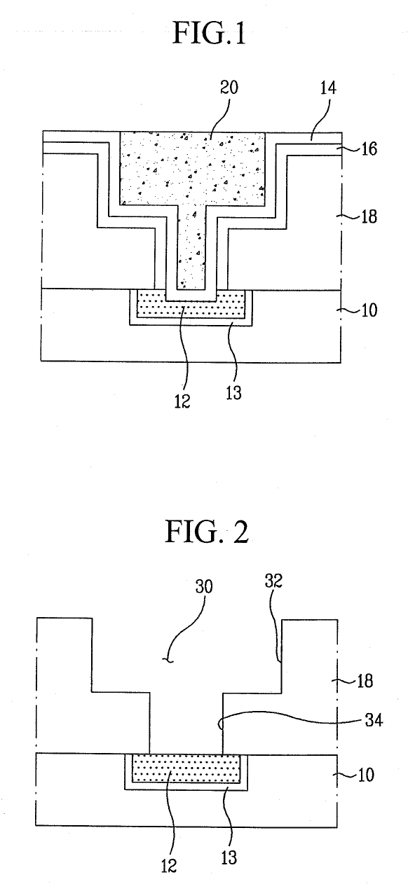

Example FIG. 1 illustrates a sectional view of a semiconductor device fabricated by a damascene process, in accordance with embodiments.

Example FIGS. 2 to 5 illustrate process sectional views of a semiconductor device, in accordance with embodiments.

Example FIGS. 6A to 6E are photographs illustrating actual coupled configurations of upper and lower metal wirings obtained by a TEM under conditions of different punch through times, in accordance with embodiments.

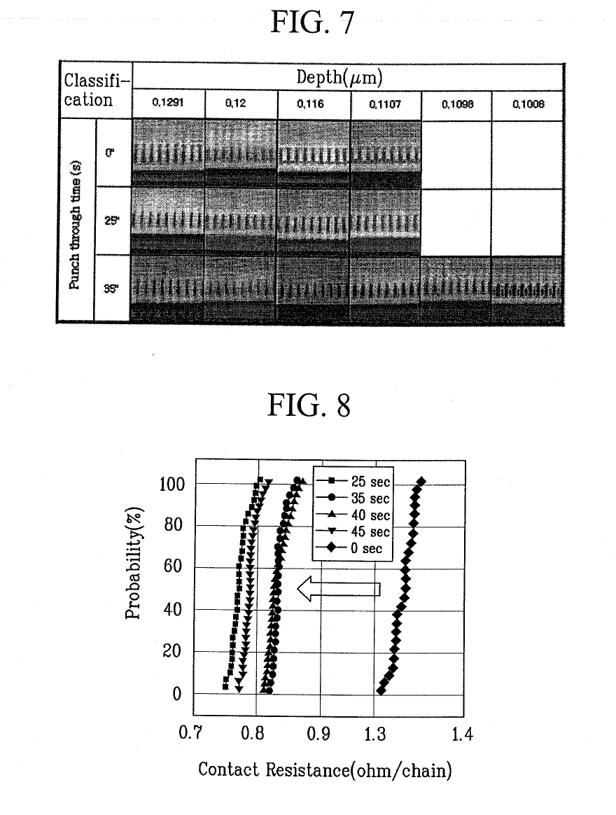

Example FIG. 7 illustrates a view showing gap-fill characteristics of an upper metal wiring under conditions of different punch through times, in accordance with embodiments.

Example FIG. 8 illustrates a graph showing a variation of contact resistance according to a variation of punch through time on the basis of a via critical dimension (CD) of 0.19 μm, in accordance with embodiments.

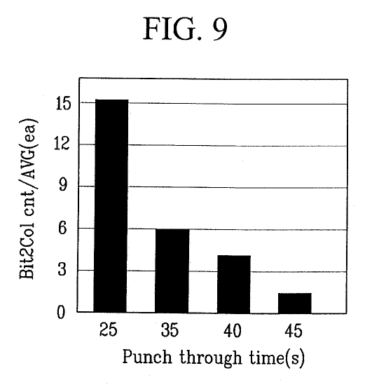

Example FIG. 9 illustrates a graph showing a variation of defect rates according to a variation of punch through time, in accordance with embodiments.

### DESCRIPTION

Example FIG. 1 illustrates a sectional view of a semiconductor device fabricated by a damascene process, in accordance with embodiments. A semiconductor device may include lower metal wiring 12 made of Cu or a similar material. Lower metal wiring 12 may be formed on and/or over semiconductor substrate 10. Lower metal wiring 12 may be surrounded by anti-diffusion film 13. In embodiments, anti-diffusion film 13 may prevent lower metal wiring 12 from being diffused into substrate 10. In embodiments, lower metal wiring 12 may be formed on a lower insulating film (e.g. a lower insulating film may be formed on and/or over semiconductor substrate 10). In embodiments, processing on and/or over a lower insulating film may be similar to processing on and/or over semiconductor substrate 10. Accordingly, for purposes of illustration, a lower insulating film may be substituted for semiconductor substrate 10 with regard to processing.

A semiconductor device may include interlayer insulating film 18 formed on and/or over semiconductor substrate 10, in accordance with embodiments. Interlayer insulating film 18 may have a damascene hole connecting to lower metal wiring 12. Anti-diffusion film 16 may be formed on side surfaces of the damascene hole. To form the anti-diffusion film 16, a desired material may be deposited and then a portion of the anti-diffusion film 16 that is at the bottom of the damascene hole may be removed, in accordance with embodiments. As illustrated in FIG. 1, a semiconductor device may have no anti-diffusion film 16 between lower metal wiring 12 and upper metal wiring 20, in accordance with embodiments. Anti-diffusion film 16 may serves to prevent copper atoms of upper copper wiring 20 from being diffused into interlayer insulating film 18. If copper atoms are significantly diffused into interlayer insulating film 18, a semiconductor device may suffer from current leakage.

Metal layer 14 may be formed between upper metal wiring 20 and anti-diffusion film 16. Metal layer 14 may be formed between upper metal wiring 20 and lower metal wiring 12. In embodiments, metal layer 14 may not be necessary and upper metal wiring 20 may be in direct contact with lower metal wiring 12.

Example FIGS. 2 to 5 illustrate process sectional views of a semiconductor device, in accordance with embodiments. As illustrated in FIG. 2, lower metal wiring 12 may be formed on and/or over semiconductor substrate 10, in accordance with embodiments. Interlayer insulating film 18 may be formed on and/or over semiconductor substrate 10, where semiconductor substrate 10 may include lower metal wiring 12. Interlayer insulating film 18 may have damascene hole 30. The damascene hole 30 may include trench 32 and/or via 34. Interlayer insulating film 18 may be made of a relatively low dielectric material having a relatively low dielectric constant k. In embodiments, interlayer insulating film 18 may be made of a porous low dielectric film, which may have an especially low dielectric constant k. In embodiments, Fluorine-doped-Silica-Glass (FSG) (k=˜3.4) may be deposited on and/or over semiconductor substrate 10 and lower metal wiring 12 (e.g. by chemical vapor deposition (CVD)). In embodiments, a portion of deposited FSG corresponding to damascene hole 30 may be removed to form interlayer insulating film 18 having a configuration illustrated in FIG. 2. In embodiments, a “via-first” method of first patterning via 34 may be used to fabricate the dual-damascene pattern illustrated in FIG. 2. In embodiments, OrganoSilicate Glass (OSG) (k=˜2.8) (e.g. instead of FSG) may be used to form interlayer insulating film 18.

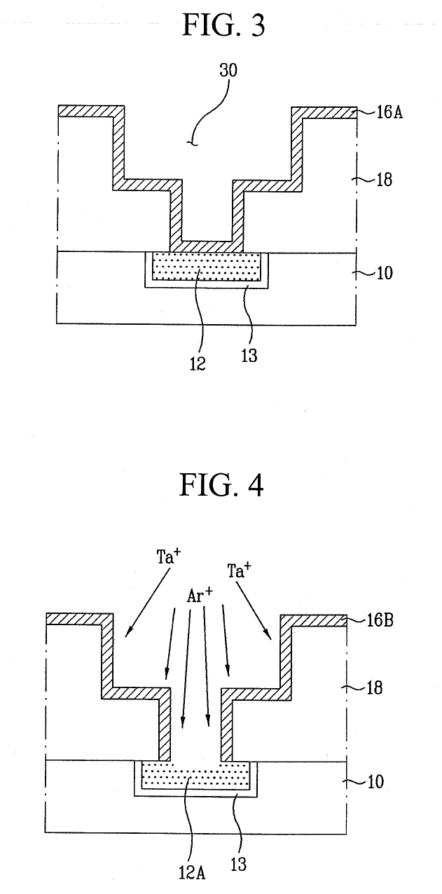

As illustrated in example FIG. 3, anti-diffusion film 16A may be formed on and/or over exposed lower metal wiring 12 at the bottom of damascene hole 30 and/or exposed interlayer insulating film 18 (e.g. including side surfaces of damascene hole 30). Anti-diffusion film 16A may be formed by depositing titanium (Ti), titanium nitride (TiN), tungsten nitride (Wn), tantalum nitride (TaN), TaN/Ta, and/or similar material. In embodiments, TaN/Ta may be deposited on and/or over interlayer insulating film 18 inside damascene hole 30 and on and/or over lower metal wiring 12 using physical vapor deposition (PVD) to from the anti-diffusion film 16A.

As illustrated in example FIG. 4, anti-diffusion film 16A formed on and/or over lower metal wiring 12 at the bottom of damascene hole 30 may be selectively removed. Anti-diffusion film 16A may be selectively removed by a plasma process using an inert gas (e.g. argon (Ar)). In embodiments, a plasma process of selectively removing anti-diffusion film 16A formed on and/or over lower metal wiring 12 may be referred to as a “punch through”. With implementation of a punch through, it may be possible to lower contact resistance by removing residues (e.g. polymers and/or impurities). In embodiments, as illustrated in FIG. 4, a portion of lower metal wiring 12A may be removed during implementation of a punch through. In embodiments, a plasma process using Ar may be implemented under a pressure of approximately 3,000 mT to 6,000 mT, DC power of approximately 100 W to 1,000 W, AC bias power of approximately 100 W to 1,000 W, and/or a temperature of approximately 20° C. to 30° C.

In embodiments, removed material of the anti-diffusion film 16A (e.g. removed during implementation of the punch through) may be re-deposited on the remaining anti-diffusion film 16A (e.g. on the side surfaces of damascene hole 30). For example, when anti-diffusion film 16A is made of TaN/Ta, copper components separated from lower metal wiring 12 as well as Ta+ and nitride may be removed from anti-diffusion film 16A during the punch through and may be re-deposited onto side surfaces of trench 32 and via 34 to form anti-diffusion film 16B. In embodiments, forming new anti-diffusion film 16B via re-deposition may compensate for losses of anti-diffusion film 16A during the punch through, which may maximize application efficiency of anti-diffusion film 16. Accordingly, in embodiments, this re-deposition may facilitate efficient and effective deposition of copper within narrow via 34.

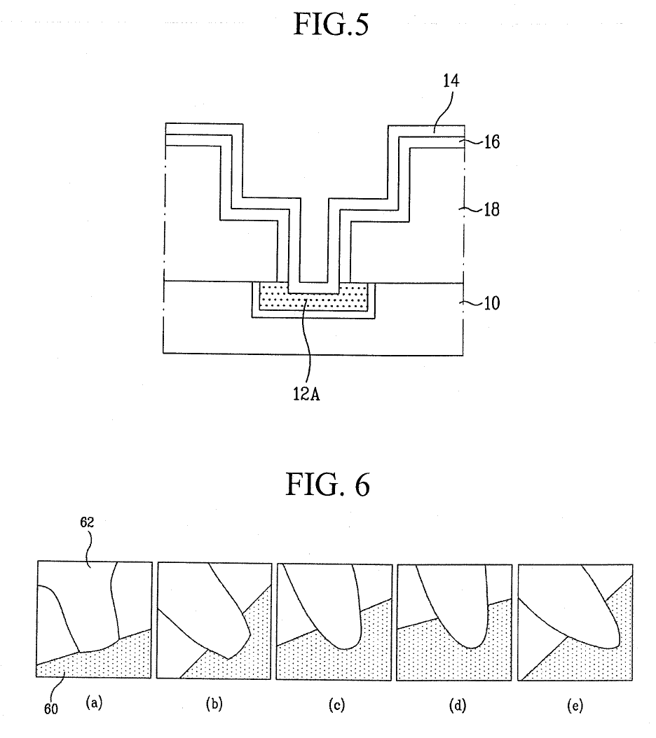

As illustrated in example FIG. 5, after selectively removing anti-diffusion film 16A from lower metal wiring 12, metal layer 14 may be formed on and/or at the bottom of damascene hole 30 and on side surfaces of damascene hole 30, in accordance with embodiments. In embodiments, metal layer 14 may be the same material as anti-diffusion film 16. In embodiments, metal layer 14 may be a different material as anti-diffusion film 16. Metal layer 14 may be formed to compensate for damage to lower metal wiring 12A during a punch through, in accordance with embodiments. In embodiments, metal layer 14 may be formed to maximize adhesive force with copper as a seed during formation of upper metal wiring 20. Example Table 1 illustrates example thicknesses of TaN/Ta anti-diffusion film 16 and/or Ta metal layer 14.

TABLE 1

Anti-Diffusion Film

| Condition | TaN | Ta | Metal Layer (Ta) |
|---|---|---|---|
| Thickness | 5~30 | 5~30 | 1~15 |
| (nm) | | | |

In embodiments, after forming metal layer 14, upper metal wiring 20 may be formed (e.g. by Electro-Chemical-Deposition (ECD)), as illustrated in FIG. 1.

In embodiments, implementation time of a plasma process (e.g. punch through time) may be adjustable. Shape variations of via 34 and/or gap-fill characteristics of upper metal wiring 20 in relation to punch through times may be analyzed using a Transmission Electron Microscope (TEM) and/or a Focused Ion Beam (FIB).

FIGS. 6A to 6E illustrate coupled configurations of lower metal wirings 12 and upper metal wiring 20 obtained by a TEM under different punch through times, in accordance with embodiments. FIG. 6A illustrates a configuration when a punch through is not applied and FIGS. 6B to 6E illustrate configurations when a punch through is implemented for 25 seconds, 35 seconds, 40 seconds, and 45 seconds, respectively, in accordance with embodiments.

In embodiments, when analyzing electric characteristics by a probe tester using four terminals, a profile of via 34 coming into contact with lower metal wiring 12 is shown in example FIGS. 6A to 6E. As illustrated in FIGS. 6A to 6E, the longer the punch through time, the deeper the interaction depth of the lower and upper metal wirings 12 and 20 may be, in accordance with embodiments. For example, side surfaces of damascene hole 30 may have optimized side coverage.

Example FIG. 7 is a view illustrating gap-fill characteristics of upper metal wiring 20 under different punch through times, in accordance with embodiments. Anti-diffusion film 16 may be formed by deposition of TaN/Ta and the punch through may be implemented for 0 seconds (O″), 25 seconds (25″), and/or 35 seconds (35″), respectively. FIG. 7 illustrates gap-fill characteristics of a Cu upper metal wiring 20 analyzed using an FIB, in accordance with embodiments. When no punch through is applied (0″), copper voids may occur from a via Critical Dimension (CD) of 0.13 μm. However, upon implementation of a punch through, void-less gap-fill may occur until the via CD reaches about 0.11 μm. A punch through may substantially remove residues, such as polymers and/or impurities, present in the via 34. While anti-diffusion film 16 located on lower metal wiring 12 is removed, the removed material of anti-diffusion film 16 may be re-deposited, which may result in improved side coverage of via 34.

Example FIG. 8 is a graph illustrating a variation of contact resistance according to variations of punch through times on the basis of a via critical dimension (CD) of 0.19 μm, in accordance with embodiments. In FIG. 8, the horizontal axis represents contact resistance and the vertical axis represents probability. In examples, a punch through was implemented for 0 seconds, 25 seconds, 35 seconds, 40 seconds, and 45 seconds, respectively.

In embodiments, as shown in example FIG. 8, when a punch through is applied, anti-diffusion film 16 at the bottom of damascene hole 30 may be removed, which may result in minimization of contact resistance of approximately 40%. As punch through time is increased, contact resistance may increase by about 0.1 Ω/cnt. For example, as illustrated in FIG. 6, as punch through time is implemented, a contact angle between lower metal wiring 12 and anti-diffusion film 16 may be reduced, which may reduce the size of via 34.

Example FIG. 9 is a graph illustrating a variation of defect rates according to variations of punch through times, in accordance with embodiments. In FIG. 9, the horizontal axis represents different punch through times and the vertical axis represents an average number of defects. For example, Bit2Co1 cnt/AVG of the ordinate means an AVeraGe (AVG) number of defective 4M Static Random Access Memories (SRAMs) in which two bits are defective in a column direction. Bit2Co1 includes both Bit2Co1_O (defects in an Odd direction) and Bit2Co1_E (defects in an Even direction).

Defects may occur when via 34 is not properly formed, which may have an effect on manufacturing yield. As illustrated in FIG. 9, increasing the punch through time diametrically may minimize defect rate. Defect rate may be minimized because residues (e.g. polymers or impurities) at the bottom of via 34 may be effectively removed as the punch through is implemented.

In embodiments, a semiconductor device and/or a method for fabricating a semiconductor device implement a punch through to substantially remove residues in vias, which may lower contact resistance and/or improve side coverage of vias. In embodiments, gap-fill characteristics may be optimized in an upper metal wiring and/or a defect rate may be minimized, which may result in optimized manufacturing yield. In embodiments, as punch through time is increased, gap-fill capabilities of an upper metal wiring may be optimized and/or contact resistance of vias may be minimized. In embodiments, byproducts (e.g. polymers present in the vias) may be removed, which may minimize a defect rate and/or optimize manufacturing yield.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a lower metal wiring over a semiconductor substrate;
forming an interlayer insulating film over the semiconductor substrate and the lower metal wiring;
forming a damascene hole in the interlayer insulating film, wherein the damascene hole exposes a portion of the lower metal wiring at a bottom of the damascene hole;
forming an anti-diffusion film over the lower metal wiring at the bottom of the damascene hole and on side surfaces of the damascene hole; and
selectively removing a portion of the anti-diffusion film formed over the lover metal wiring at the bottom portion of the damascene hole.

2. The method of claim 1, wherein said selectively removing comprises a plasma process using inert gas.

3. The method of claim 2, wherein the plasma process is implemented using argon (Ar) as the inert gas under at least one of:
a pressure between approximately 3,000 mT to 6,000 mT;
DC power between approximately 100 W to 1,000 W;
AC bias power between 100 W and 1,000 W; and
temperature between approximately 20° C. and 30° C.

4. The method of claim 2, comprising re-depositing material of the anti-diffusion layer that was removed by the plasma process on the side surfaces of the damascene hole.

5. The method of claim 4, comprising:
separating a lower metal material from a portion of the lower metal wiring at the bottom of the damascene hole by the plasma process; and
depositing the separated lower metal material on the side surfaces of the damascene hole.

6. The method of claim 5 comprising forming a metal layer over the side surfaces of the damascene hole and over the bottom of the damascene hole, wherein the portion of the metal layer that is formed on the side surfaces is formed over the separated lower metal material that was deposited on the side surfaces.

7. The method of claim 5, wherein thickness of the re-deposited anti-diffusion film material over the side surfaces of the damascene hole corresponds to the implementation time of the plasma process.

8. The method of claim 1, comprising forming a metal layer over the bottom of the damascene hole and over the side surfaces of the damascene hole after said selectively removing the anti-diffusion film.

9. The method of claim 8, comprising forming an upper metal wiring by filling metal material in the damascene hole after forming the metal layer.

10. The method of claim 8, wherein the metal layer and the anti-diffusion film comprises the same material.

11. The method according to claim 8, wherein:
the anti-diffusion film has a thickness between approximately 10 nm and 60 nm; and
the metal layer has a thickness between approximately 1 nm and approximately 15 nm.

12. The method of claim 1, wherein:
the lower metal wiring comprises copper (Cu); and
the anti-diffusion film comprises at least one of titanium (Ti), titanium nitride (TiN), tungsten nitride (Wn), tantalum nitride (TaN), and TaN/Ta.

13. The method of claim 1, wherein the interlayer insulating film comprises a low dielectric film having a low dielectric constant k.

14. The method of claim 13, wherein the low dielectric film is a porous low dielectric film.

15. The method of claim 1, wherein said selectively removing the anti-diffusion film substantially simultaneously removes at least one of residues, polymers, and impurities from the damascene hole.

16. An apparatus comprising:
a lower metal wiring formed over a semiconductor substrate;
an interlayer insulating film formed over the semiconductor substrate and the lower metal wiring, wherein the interlayer insulating film has a damascene hole formed which exposes the lower metal wiring;
an anti-diffusion film formed over side surfaces of the damascene hole; and
an upper metal wiring formed over the anti-diffusion film and the lower metal wiring at a bottom of the damascene hole.

17. The apparatus claim 16, comprising a metal layer formed between the upper metal wiring and the anti-diffusion film and formed between the upper metal wiring and the lower metal wiring.

18. The apparatus of claim 16, comprising a lower insulating film formed between the semiconductor substrate and the interlayer insulating film, wherein the lower metal wiring is formed over the lower insulating film.

19. The apparatus of claim 16, wherein the lower metal wiring comprises copper (Cu).

20. The apparatus of claim 16, wherein the anti-diffusion film comprises at least one of titanium (Ti), titanium nitride (TiN), tungsten nitride (Wn), tantalum nitride (TaN), and TaN/Ta.
